(19) United States
(12) Patent Application Publication
(10) Pub. No.: US 2024/0222127 A1
(43) Pub. Date: Jul. 4, 2024

(54) METHOD FOR WAFER TREATMENT

(71) Applicant: Hua Hsu Silicon Materials Co., Ltd., Taichung City (TW)

(72) Inventors: Chiao-Yang Cheng, Taichung City (TW); Hsiang-Yi Liu, Taichung City (TW); Chi-Yao Tseng, Taichung City (TW); Thi-Yen Thu Le, Taichung City (TW)

(21) Appl. No.: 18/237,910

(22) Filed: Aug. 25, 2023

(30) Foreign Application Priority Data
Dec. 29, 2022 (TW) 111150513
Dec. 29, 2022 (TW) 111150531

(51) Int. Cl. H01L 21/268; H01L 21/66; H01L 21/67

(52) U.S. Cl. CPC H01L 21/268; H01L 21/67092; H01L 22/12; H01L 2221/68327

(57) ABSTRACT

A method for wafers treatment is disclosed. First, a wafer including a wafer base is provided, where the wafer base includes a surface layer. Second, a first laser process is performed, wherein the surface layer of the wafer is irradiated with a first laser to modify the surface layer. The first laser is associated with a first parameter group. Next, a second laser process is performed, wherein the surface layer of the wafer is irradiated with a second laser to modify the surface layer. The second laser is associated with a second parameter group. Modification of the surface layer includes at least one of removing the surface layer, changing the crystallinity of the surface layer, or changing the surface roughness of the surface layer. The first parameter group corresponds to the second parameter group.

### BACKGROUND OF THE INVENTION

### 1. Field of the Invention

The present invention relates to a method for wafer treatment. In particular, the present invention is directed to a method for recycling a wafer by the wafer treatment and to a method for processing a wafer surface by the wafer treatment.

### 2. Description of the Prior Art

In the semiconductor manufacturing process, a variety of semiconductor manufacturing equipment is used, such as thin film deposition equipment, photolithography equipment, ion implantation equipment, diffusion equipment, etc., to fabricate the required integrated circuits in a semiconductor wafer.

The current common wafer preparation method is the Czochralski method, which can effectively form wafer ingots with low lattice defects. Wafers of expected thickness can be obtained by applying appropriate cutting methods to the wafer ingots. During the cutting process, cutting marks and structural defects will inevitably be formed on the surface and the edge of the wafer. In order to repair or remove the cutting marks and the structural defects on the wafer, it generally requires performing multiple processing steps, such as grinding, chamfering, etching, polishing, etc. However, these processing steps are complicated, and the time cost is very high. Therefore, the industry has an urgent need for a simple wafer surface repair method.

On the other hand, in order to confirm whether the process parameters of the process equipment meet the specifications, test wafers are usually used to pass through different process equipment (such as an epitaxial process, a thin film process, a patterning process) to evaluate and adjust the process parameters of the process equipment before the formal production of integrated circuits. In order to reuse these processed test wafers, it is often necessary to go through a complicated recycling process to regenerate the test wafers (reclamation), and conventional test wafer recycling includes multiple steps such as wet etching, film removal, grinding, and polishing.

In addition to test wafers, prime wafers may also need recycling and regenerating due to structural defects and/or electrical defects after being processed by the process equipment. Similarly, the regeneration process is complicated and usually includes multiple steps, such as wet etching to remove the film, grinding, and polishing.

Wet etching and film removal; because it usually comes with the use of chemicals such as strong acids or strong alkalis, which greatly increases the risk and the pollution of the wafer recycling steps, which is not conducive to environmental protection and sustainable development. Therefore, a safe and simple wafer recovery method is urgently needed in the industry.

### SUMMARY OF THE INVENTION

In order to achieve the aforementioned objectives, the present invention provides a method for wafers treatment. This method includes providing a wafer include a wafer base, wherein the wafer base includes a surface layer. The wafer treatment method further involves conducting a first laser process, wherein the surface layer of the wafer is irradiated with a first laser to modify the surface layer; the first laser is associated with a first parameter group. A second laser process is performed, wherein the surface layer of the wafer is irradiated with a second laser to modify the surface layer; the second laser is associated with a second parameter group. The modification of the surface layer includes at least one removing at least part of the surface layer, changing the crystallinity of the surface layer, and changing the roughness of the surface layer, and the first parameter group corresponds to the second parameter group. The first parameter group corresponds to the second parameter group. The method for wafer treatment provided by the present invention enables a simple manner to modify the surface layer of the wafer and effectively enhances the efficiency of wafer surface treatment.

In order to achieve the above objectives, the method for wafer treatment provided by the present invention may be a wafer recycling method, which includes providing a wafer comprising a wafer base and a thin film. The wafer base includes a main surface, a surface layer, and a base layer. The thin film is disposed of on the main surface and includes a dielectric portion, a semiconductor portion, and a conductor portion. The wafer recycling method also includes performing the first laser process, where the main surface or the surface layer of the wafer is irradiated with a first laser to induce separation at the interface between the main surface and the thin film. The second laser process is performed to irradiate the main surface or the surface layer of the wafer with the second laser, thereby changing the surface roughness of the main surface. Furthermore, the third laser process is performed to irradiate the main surface or the surface layer of the wafer with a laser, thereby changing the crystallinity of the surface layer. The wafer recycling method provided by the present invention possesses high safety and simplicity; the wafer recycling method eliminates the requirement for a wet etching process, which can further enhance the green value of the present invention.

In order to achieve the aforementioned objectives, the method for wafers treatment provided by the present invention may be a method for processing a wafer surface, which includes providing a wafer comprising a front side, a back side, and an edge, where at least one of the front side, the back side, and the edge has a damaged surface layer. This method includes performing a first laser process to irradiate the damaged surface layer of the wafer with the first laser so as to remove the damaged surface layer. During the first laser process, the first laser is characterized by a first parameter group, including a first power density, a first spot size, and a first focal offset distance. Then, the second laser process is performed, where the front side and the back side of the wafer are irradiated with a second laser to reduce the surface roughness of the front side and the back side. During this second laser process, the second laser is characterized by the second parameter group, including a second power density, a second spot size, and a second focal offset distance. The values of at least two of the second power density, the second spot size, and the second focal offset distance are smaller than the corresponding values of the first power density, the first light spot size, and the first focal offset distance. The method for a wafer surface treatment provided by the present invention is characterized by its simplicity, as the method eliminates the requirement for complex mechanical polishing steps and effectively enhances the efficiency of the wafer surface treatment.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a perspective view of the multi-laser process in the method for a wafer treatment of the present invention.

FIG. 2 illustrates a perspective view of the laser process of the present invention.

FIG. 3 illustrates a top view of a laser scanning path for carrying out a laser process in the present invention.

FIG. 4 illustrates a perspective cross-sectional view of a wafer that is cut from a silicon ingot.

FIG. 5 illustrates a perspective view of the first laser process, the second laser process, and the third laser process according to the first example of the present invention.

FIG. 6 illustrates a perspective cross-sectional view of a multi-laser process in accordance with the first example of the present invention.

FIG. 7 illustrates a partial cross-sectional view of a test wafer to be recovered according to a second example of the present invention.

FIG. 8 illustrates a schematic diagram of performing the second laser process or the third laser process after the first laser process according to the second example of the present invention.

### DETAILED DESCRIPTION

In order to make a person of ordinary skill in the technical field of the present invention to further understand the present invention, several preferred embodiments of the present invention are given below, and in conjunction with the attached drawings, the details and desired achievement of the present invention are described. Moreover, the person in the technical field of the present invention may also refer to the following embodiments without departing from the spirit of the present invention and replace, reorganize, and mix the features in several different embodiments to complete other implementations.

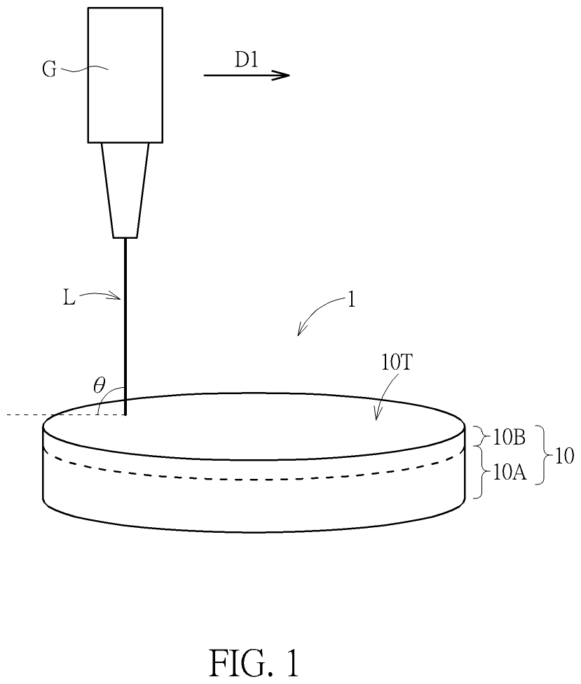

FIG. 1 illustrates a perspective view of the multi-laser process in the method for wafer treatment of the present invention. As shown in FIG. 1 in the local area of the wafer 1, the wafer 1 includes a wafer base 10, for example, a single-crystal wafer substrate composed of one or more elements such as silicon, silicon carbide, gallium nitride, aluminum nitride, gallium arsenide, indium phosphide, sapphire, etc., but the present invention is not limited thereto. According to the different rigidity properties of the material of the wafer base 1, the thickness of the wafer base 10 may range from 0.3 mm to 1.5 mm. The wafer base 10 includes a base layer 10A, a surface layer 10B, and a main surface 10T. According to different manufacturing processes of the wafer, the thickness of the surface layer 10B may range from 50 μm to 500 μm. In one embodiment, the surface layer 10B is a layer region whose crystal lattice or structure is affected by a process above the main surface 10T, and the base layer 10A is a base region whose crystal lattice or structure is not affected by the process. In another embodiment, the surface layer 10B includes an insulating trench (not shown) and a doped region (not shown), while the base layer 10A includes a doped region (not shown).

Firstly, along multiple paths parallel to the first direction D1, a first laser process is carried out and performed on the entire main surface 10T, and the first laser is associated with a first parameter group. For example, the laser L is generated by the laser generating device G, and the laser L irradiates the surface layer 10B and/or the main surface 10T of wafer 1, thereby modifying the surface layer 10B. Next, along the multiple paths parallel to the first direction D1, a second laser process is carried out, and the second laser is associated with a second parameter group. For example, the laser L is generated by the laser generating device G, and the laser L irradiates the surface layer 10B and/or the main surface 10T of the wafer 1 to modify the surface layer 10B. Then, optionally, along the multiple paths parallel to the first direction D1, a third laser process is carried out, and the third laser is associated with a third parameter group. For example, the laser L is generated by the laser generating device G, and the laser L irradiates the surface layer 10B and/or the main surface 10T of the wafer 1 to modify the surface layer 10B. There may be more laser processes to be similarly carried out in the method for wafers treatment of the present invention.

Modification of the surface layer 10B by means of the multi-laser processes may change one or more properties of the surface layer 10B. For example, it is possible to remove at least some of the surface layer 10B, or change the crystallinity of the surface layer 10B, or change the roughness of the surface layer 10B, but the present invention is not limited thereto. When the properties of surface layer 10B are changed, different functions and usages can be produced accordingly, which will be elaborated in detail in the following examples.

The parameter group of each laser process may correspond to one another to correspondingly result in different functions and usages. For example, the first parameter group corresponds to the second parameter group, or the second parameter group corresponds to the third parameter group. If there are more laser processes to be carried out in the method for wafers treatment of the present invention, other parameter groups may have similar corresponding relationships. As an illustration, the parameter group encompasses parameters such as laser power density, laser spot size, and laser focal offset distance, but the present invention is not limited thereto.

It should be noted that irradiating with a laser on a certain surface or on a certain layer, as mentioned herein, means that the focal point of the laser is on the surface or in the layer. For example, when the laser L irradiates the main surface 10T, it means that the focal point of the laser L emitted by the laser generating device G is on the main surface 10T. When the laser L irradiates the surface layer 10B, it means that the focal point of the laser L emitted by the laser generating device G is in the surface layer 10B.

In FIG. 1, the laser L forms an angle θ with the main surface 10T of wafer 1. The laser angles in the first laser process, second laser process, and third laser process can range from 30° to 90°. Depending on the specific laser processing region, such as the edge area of wafer 1, the laser angles in the first, second, and third laser processes can range from 30° to 60°.

According to different requirements, the execution order of the first laser process, the second laser process, and the third laser process may be optionally arranged or simultaneously. For example, the first laser process is carried out prior to the second laser process and the third laser process, or the first laser process, the second laser process, and the third laser process are carried out in order, but the present invention is not limited thereto.

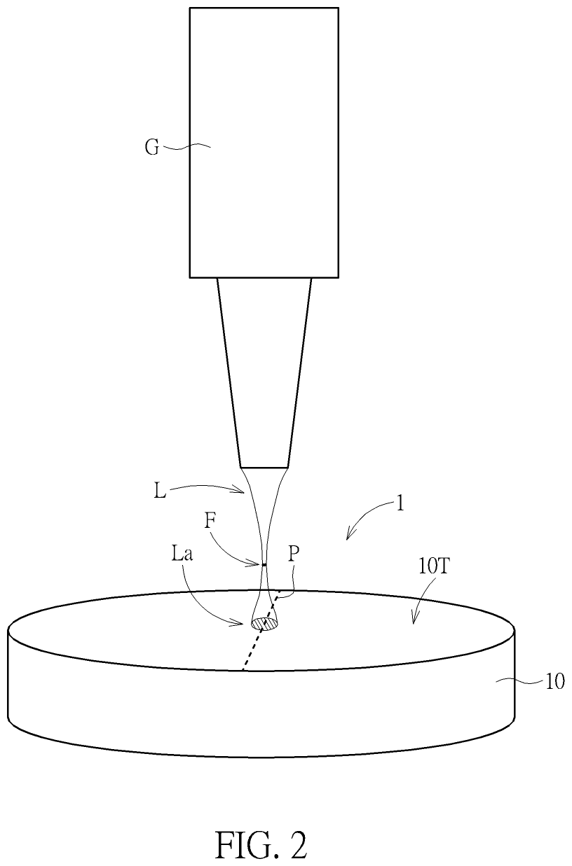

FIG. 2 illustrates a perspective view of the laser process of the present invention to further enlarge the laser L emitted by the laser generating device G. The laser generating device G may carry out the first laser process, second laser process, and third laser process along the scanning path P and other scanning paths. The laser L emitted by the laser generating device G has a focal point F, and the laser L has a spot La on the outermost exposed surface of wafer 1 (such as the main surface 10T or the surface of a film (not shown)). In one embodiment, the diameter of the spot size of the laser L of the first laser process is greater than 0.05 mm or greater than 0.1 mm. In another embodiment, the spot size of the laser of the first laser process is greater than the laser spot size of the laser of the second laser process and greater than the laser spot size of the laser of the third laser process. It should be noted that the outermost exposed surface of wafer 1 still has spot La when the focal point F of the laser L is located below the outermost exposed surface, although the focal point F of the laser L in FIG. 2 is located above the outermost exposed surface of the wafer 1.

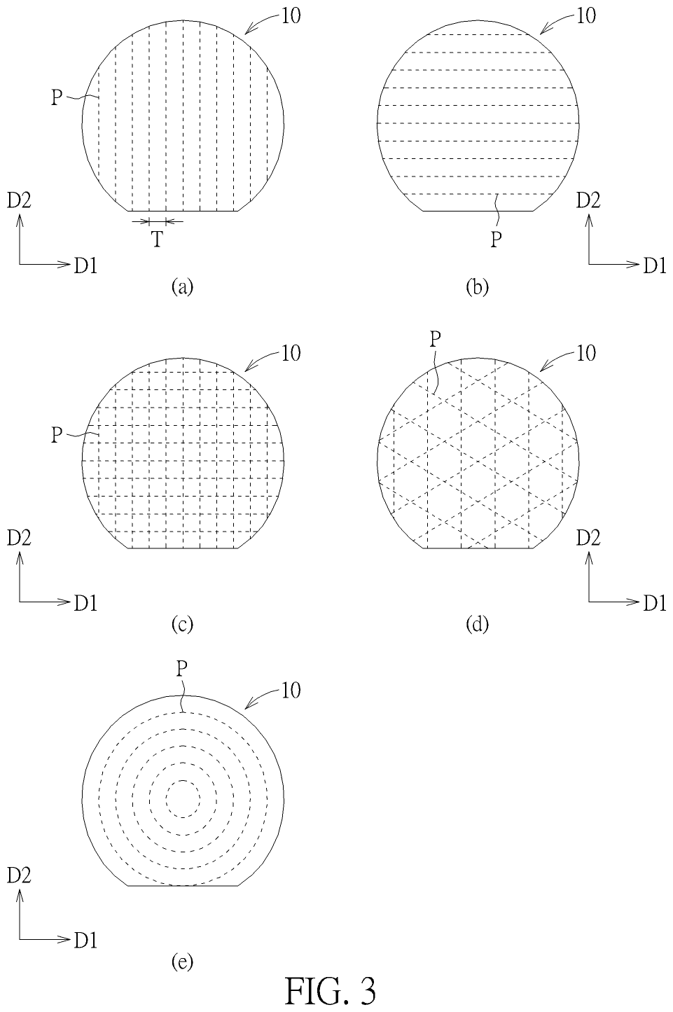

FIG. 3 illustrates a top view of a laser scanning path for carrying out a laser process in the present invention. The scanning paths P of the first laser process, the second laser process, and the third laser process of the present invention may be the same or different from each other. As shown in FIG. 3(a), the scanning path P may be linear along a second direction D2, and there is a scanning width T between two adjacent scanning paths P. According to different requirements, for example, when the diameter of the laser spot size is greater than 5 μm, the scanning width of the laser can range from 2 μm to 100 μm so that the wafer 1 can be fully scanned. The scanning pitch of the laser L is the distance between the laser L emitted by the laser generating device G. In one embodiment, the scanning pitch ranges from 1 μm to 100 μm. As shown in FIG. 3(b), the scanning path P may be linear along a first direction D1, as shown in FIG. 3(c), the scanning path P may be linear along the first direction D1 before linear along the second direction D2, or linear along the second direction D2 before linear along the first direction D1, as shown in FIG. 3(d) The scanning path P may be linear along the second direction D2 before along the other two different scanning directions in sequence to form a plurality of polygonal scanning regions, as shown in FIG. 3(e), the scanning path P may be along concentric circular paths.

According to different requirements, the scanning paths of the first laser process, the second laser process, and the third laser process may be any combination from FIG. 3(a) to FIG. 3(e), but the present invention is not limited thereto. In one embodiment, the scanning path of the first laser process is shown in FIG. 3(c), the scanning path of the second laser process is shown in FIG. 3(d), and the scanning path of the third laser process is shown in FIG. 3(e). In another embodiment, the scanning path of the first laser process is shown in FIG. 3(d), the scanning path of the second laser process is shown in FIG. 3(c), and the scanning path of the third laser process is shown in FIG. 3(a).

The method for wafer treatment of the present invention is not limited to the aforementioned descriptions. Various examples of the method for wafer treatment of the present invention are provided below, for example, but not limited to a method for processing a wafer surface or a wafer recycling method. In order to highlight and distinguish the differences between various examples or variants, it is not necessary to use the same reference numerals to mark similar elements in the following, and similar descriptions will not be elaborated again. In addition, the material and thickness of each film layer and the conditions of the process steps in each example of the present invention may be the same or different, so similar descriptions will not be elaborated again.

### Example 1

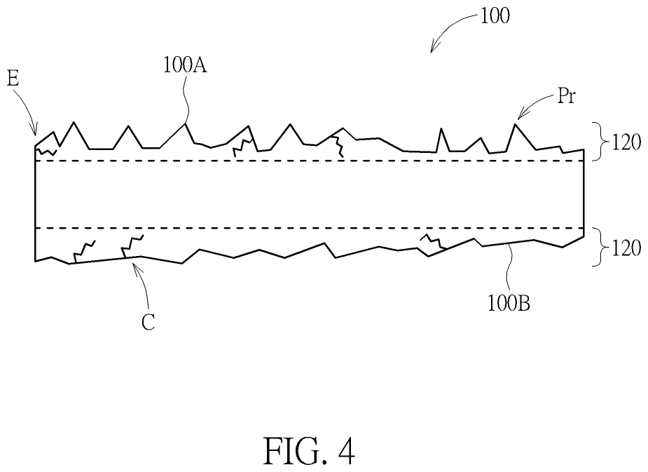

Please refer to FIG. 4, which illustrates a perspective cross-sectional view of a wafer that is cut from a silicon ingot. FIG. 4 is a schematic cross-sectional view of the wafer 100. The wafer 100 includes a front side 100A, a back side 100B, and an edge E. Since the wafer 100 is obtained by cutting (for example, wire sawing) a silicon ingot, the front side 100A, the back side 100B, and the edge E of the wafer 100 each have a damaged surface layer 120 (for example, in the surface layer 10B shown in FIG. 1). The damaged surface layer 120 includes a plurality of cutting marks C and/or a plurality of structural defects (for example, irregular protrusions Pr and lattice dislocations in local regions (not shown)). According to the quality and the precision of the wafer cutting, the thickness of the damaged surface layer 120 can range from 1 μm to 500 μm. Compared with the core body of the wafer 100, reprocessing is necessary to remove the damaged surface layer 120 of the front side 100A, the back side 100B, and the edge E or to trim it to the thinnest or even close to nothing left to facilitate the processed wafers for use in a subsequent semiconductor process or in an epitaxial process (in particular with respect to this process) and to prevent the accumulation of stress or the formation of lattice defects, which is not conducive to the fabrication of the semiconductor components since the lattice structure of the damaged surface layer 120 is less ordered, and the surface is rough.

It should be noted that for wafers that have just been freshly cut from a silicon ingot, the characteristics of the front side and the back side are substantially not different. Therefore, the front side 100A and back side 100B of the wafer 100 in FIG. 4 are defined in the subsequent processes. Specifically speaking, the front side 100A of the wafer 100 is for use in the subsequent epitaxial process, the thin film deposition process, or serving as the surface to carry the interconnections so as to form a surface facing the semiconductor elements, while the back side 100B of the wafer 100 is located at the opposite side and the wafer 100 may be thinned by a subsequent appropriate grinding process to obtain a desired thickness.

According to different ways of cutting, the damaged surface layer 120 of the wafer obtained by cutting from the silicon ingot may be present on at least one of the front side 100A, the back side 100B, and the edge E (i.e. some or all of the front side 100A, the back side 100B, and the edge E may include the damaged surface layer). In this embodiment, the damaged surface layer 120 is present on the front side 100A, the back side 100B, and the edge E at the same time. According to another embodiment, the damaged surface layer 120 is mainly present on the front surface 100A, and the back surface 100B (for example, the proportion of the damaged area exceeds 50%), and only a small amount of the damaged surface layer 120 is present on the edge E (for example, the proportion of the damaged area is less than 50%).

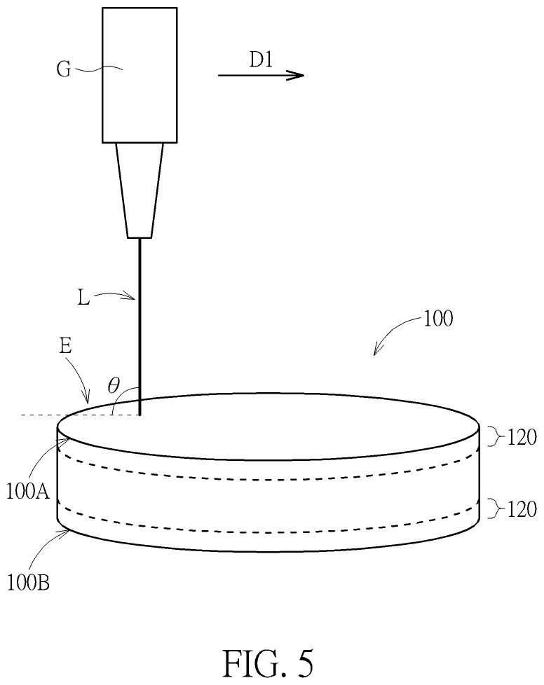

FIG. 5 illustrates a perspective view of the first laser process, the second laser process, and the third laser process according to an embodiment of the present invention. Firstly along the multiple paths parallel to the first direction D1, the first laser process is carried out on the entire front side 100A, the entire back side 100B, and the entire edge E. For example, the laser L is generated by the laser generating device G to irradiate the damaged surface layer 120 of the front side 100A, the back side 100B, and the edge E of the wafer 100 so as to remove the damaged surface layer 120. The first laser process is performed, where the laser L is characterized by a first parameter group, such as the first power density, the first spot size, and the first focal offset distance. Then, along the multiple paths parallel to the first direction D1, the second laser process is performed. For example, the laser L is generated by the laser generating device G to irradiate the front side 100A and back side 100B of the wafer 100 to reduce the surface roughness of the front side 100A and the back side 100B or to remove shallow defects at the same time. The second laser process is performed, where the laser L is characterized by the second parameter group, such as the second power density, the second spot size, and the second focal offset distance. The values of at least two of the second power density, the second spot size, and the second focal offset distance in the second parameter group are smaller than the values of the first power density, the first spot size, and the first focal offset distance in the corresponding first parameter group. For example, the second power density and second focal offset distance of the second laser process are respectively smaller than the first power density and first focal offset distance of the first laser process, or the second power density, second focal offset distance, and second spot size of the second laser process are respectively smaller than the first power density, first focal offset distance and first spot size of the first laser process. In this way, the first laser process may remove a thicker and more defective damaged surface layer 120, while the second laser process may reduce the surface roughness of the wafer 100, or further make the surface roughness uniform or remove shallow defects of the wafer 100.

Optionally, a third laser process may be performed along the multiple paths parallel to the first direction D1 after the second laser process is carried out. For example, the laser L is generated by the laser generating device G to irradiate the front side 100A, the back side 100B, and edge E of the wafer 100 so that the front side 100A, the back side 100B, and edge E are annealed, which may reduce the point defect density caused by oxygen precipitation inside the wafer or the surface region of the wafer (such as a depth in a range from 0 to 100 μm from the wafer surface), or to further purge oxygen from the wafer. The third laser process is performed, where the laser L is characterized by a third parameter group, such as a third power density, a third spot size, and a third focal offset distance, and the third parameter group corresponds to the first parameter group or the second parameter group. For example, the third power density is smaller than the first power density and second power density, and the third spot size is larger than the first spot size and second spot size. For example, the third power density of the third laser process is smaller than the first power density and second power density, and the third focal offset distance ranges from 0 to −100 μm. Thus, the third laser process may increase the crystallinity of the shallow region of the wafer 100 and eliminate the original lattice defects without affecting the surface roughness of the wafer 100.

The main surface region of the wafer 10 (i.e., the front side 100A or back side 100B) and the edge region are conventionally subjected to lapping and chamfering by using grinding slurry or grinding wheels. The grinding slurry of different particle sizes or the grinding wheels of different thicknesses are replaced to gradually reduce the roughness of the wafer surface and the edge during the grinding process in addition to additional damage layers which are caused to the edge region during the grinding process. The method for processing a wafer surface provided by the present invention may carry out different laser processes to replace the conventional grinding process and the conventional grinding chamfering process by adjusting the laser angles to reduce the cost of the wafer surface treatment and improve the efficiency of the wafer surface treatment at the same time.

In one embodiment, the laser in the first laser process, the second laser process, or the third laser process may be replaced with a suitable high-energy pulse beam.

According to different requirements, the front side 100A and back side 100B may be subjected to a surface roughness meter or a scanning electron microscope (SEM) to determine or adjust the actual power density, actual spot size, and actual focal offset distance of the second laser process and the third laser process prior to the second laser process and the third laser process. In one embodiment, the second laser process and third laser process are carried out directly following the first laser process.

The protrusions Pr of the wafer 100 in FIG. 1 may be cracked, melted, or vaporized when the first laser process and second laser process are carried out. In one embodiment, the damaged surface layer 120 of the front side 100A, the back side 100B, and the edge E of the wafer 100 is completely removed after the first laser process is carried out, and the wafer 100 after processed in the present invention has a thickness ranging from 0.25 mm to 1.0 mm.

In one embodiment, the pulse frequency of the first laser process, the second laser process, and the third laser process range from 10 kHz to 100 kHz, and the pulse width ranges from 100 nanoseconds to 500 nanoseconds. The first power density of the first laser process ranges from 500 μJ/pulse to 700 μJ/pulse, the second power density of the second laser process ranges from 200 μJ/pulse to 500 μJ/pulse, and the third power density of the third laser process is less than 500 μJ/pulse, or smaller. In another embodiment, the first power density of the first laser process ranges from 600 μJ/pulse to 800 μJ/pulse, the second power density of the second laser process ranges from 300 μJ/pulse to 600 μJ/pulse, and the third power density of the third laser process is less than 600 μJ/pulse, or even smaller. It should be noted that the power density of the present invention refers to the energy of each laser pulse, and the energy received by the irradiated surface of the wafer per unit of time is not only related to the power density but also related to the pulse width. Specifically speaking, the energy (ρJ/ns) received by the irradiated surface of the wafer may be obtained by dividing the power density by the pulse width.

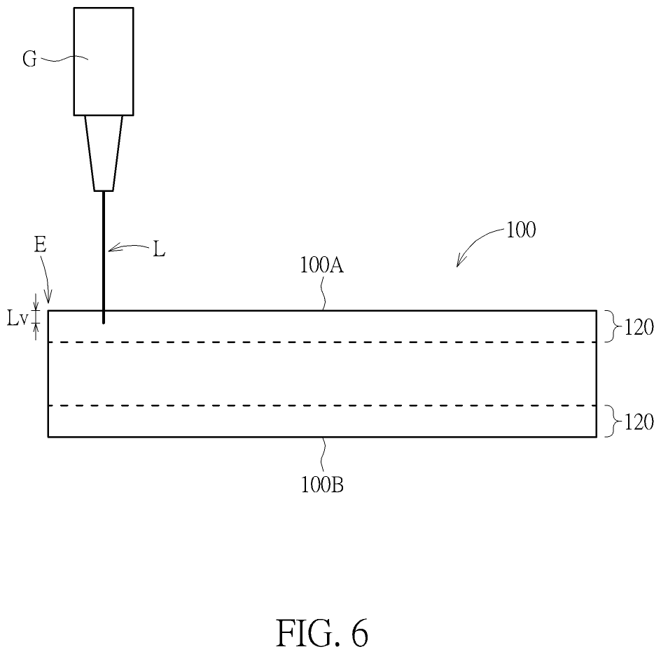

FIG. 6 illustrates a perspective cross-sectional view of a multi-laser process in accordance with an embodiment of the present invention. FIG. 6 illustrates a cross-sectional view of wafer 100, and the illustrations of FIG. 6 omit cutting marks and protrusions of the damaged surface layer 120. In one embodiment, a first laser process is carried out to remove the damaged surface layer 120 of the front side 100A, the back side 100B, and the edge E and the focal point of the laser L is on the front side 100A or the back side 100B, or within 5 μm below the front side 100A or the back side 100B. The second laser process is carried out to reduce the surface roughness of the front 100A and the back 100B, and the focal point of the laser L is on the front 100A or the back 100B or within 10 μm below the front 100A or the back 100B. The third laser process is carried out to anneal the front 100A, the back 100B, and the edge E, and the focal point of the laser L is within 100 μm below the front 100A or the back 100B. It should be noted that the focal offset distance reference plane is the average height reference plane of the protrusions (not shown) of the front 100A or the back 100B, such as the reference line formed by the arithmetic mean height (Sa). In other words, the focal point of the laser L falls on the focal offset distance reference plane when the focal offset distance Lv is 0; the focal point of the laser L is 10 μm below the focal offset distance reference plane when the focal offset distance Lv is −10 μm.

In order to make the front side 100A and back side 100B of the wafer 100 meet the surface roughness specification of the subsequent planarization process, the protrusions (not shown) on the front side 100A and the back side 100B may be melted or vaporized by carrying out the second laser process, so that the arithmetic average height (Ra) of the front side 100A and the back side 100B is less than 1 μm, or even not greater than 100 nm. For example, the front side 100A of the wafer 100 has a first roughness (for example, the arithmetic mean height (Ra)) prior to the second laser process, and the front side 100A of the wafer 100 has a second roughness following the second laser process (for example, the arithmetic mean height (Ra)), and the first roughness is greater than the second roughness. In addition, the uniformity of the surface roughness of the wafer 100 may be further improved by means of the second laser process. In one embodiment, an optional planarization process (such as chemical mechanical polishing) may be carried out on the front side 100A and the back side 100B to further reduce the surface roughness of the front side 100A and the back side 100B after the second laser process is carried out, and then an optional cleaning process (such as ultrasonic cleaning) may be carried out on the front side 100A and the back side 100B of the wafer 100 to remove the products or residues that are generated after the laser treatment.

In order to eliminate the damage caused by the first laser treatment to the wafer 100, such as but not limited to lattice dislocation or contaminant doping, a third laser process may be further carried out to anneal the wafer 100. The first laser process may at least partially or completely remove the damaged surface layer 120 of the front side 100A and the back side 100B, but the damage caused during the first laser process may be distributed on the bottom of the damaged surface layer 120 adjacent to the front side 100A and the back side 100B. The damage caused by the first laser process may be further repaired by carrying out the third laser process, thereby releasing the stress on the front side 100A and the back side 100B. Specifically speaking, the overall entropy of the wafer 100 can thus be reduced, and microscopically speaking, the amorphous region or the polycrystalline region can be repaired to yield a single crystal lattice arrangement.

According to different requirements, the third laser process may be carried out more than once. In one embodiment, the first laser process, the third laser process, the second laser process, and the third laser process in the method for processing a wafer surface of the present invention may be carried out in sequence, and the third laser process is carried out respectively after the first laser process and the second laser process to repair the damage caused by the previous process.

According to different requirements, the first laser process, the second laser process, and the third laser process may be pulsed lasers with the same or different pulse widths. In one embodiment, the first laser process and second laser process may be nanosecond laser, picosecond laser, or femtosecond laser, and the third laser process may be nanosecond laser. By using a pulse laser, the selected local regions may be cracked, melted, or vaporized without affecting unselected regions.

The method for processing a wafer surface of the present invention may include step S1, step S2, and step S3. In step S1, a wafer is provided. In step S2, a first laser process is performed, wherein the damaged surface layer on the front side, the back side, and the edge of the wafer are irradiated with laser; so as to remove the damaged surface layer of the wafer. In step S3, a second laser process is performed, wherein the front side and back side of the wafer are irradiated with a laser to reduce the surface roughness of the front side and the back side of the wafer.

### Example 2

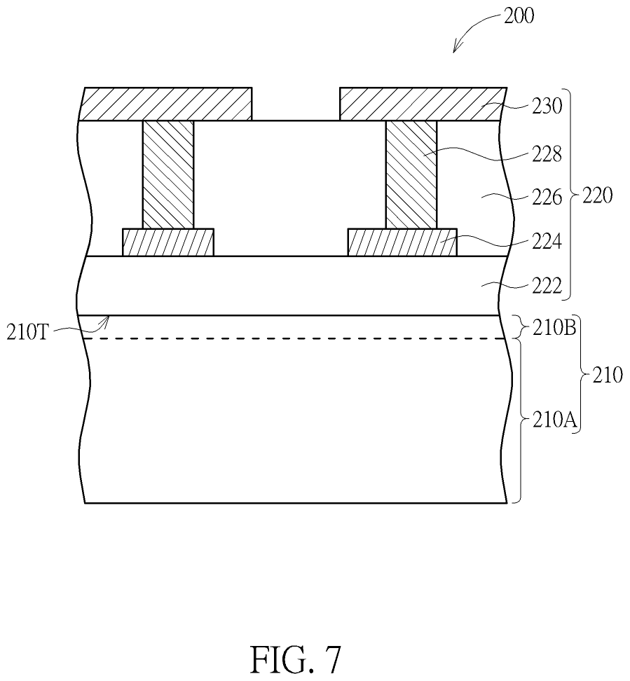

FIG. 7 illustrates a perspective partial cross-sectional view of a test wafer to be recovered. A partial region of the test wafer 200 is shown in FIG. 7, and the test wafer 200 includes a wafer base, such as a test wafer base 210. The test wafer base 210 includes a base layer 210A, a surface layer 210B, and a main surface 210T. According to different process, tests carried out on the test wafer 200, the thickness of the surface layer 210B ranges from 50 μm to 500 μm. In one embodiment, the surface layer 210B is a layer region whose lattice or structure is affected by a process carried out above the main surface 210T, and the base layer 210A is a base region whose lattice or structure is not affected by the process. In one embodiment, there are insulating trenches and doped regions included within the surface layer 210B, while the base layer 210A includes doped regions.

A thin film 220 may be disposed on the main surface 210T of the test wafer base 210 and includes a dielectric portion, a semiconductor portion, and a conductor portion, but the present invention is not limited thereto. In one embodiment, the dielectric portion may include a gate insulating layer, a gate spacer, an interlayer dielectric layer, or a passivation layer; the semiconductor portion may include a stress buffer layer, a high resistance layer or a gate semiconductor layer; the conductor portion may include a field plate, electrodes, an interconnect layer or a pad layer, but the present invention is not limited thereto. In one embodiment, a semiconductor layer 222, a metal electrode 224, and a dielectric layer 226 may be disposed of on the main surface 210T of the test wafer 200. A conductive interconnection layer, such as a plurality of plugs 228, may be disposed of in the dielectric layer 226. The plugs 228 may be formed by forming a plurality of trenches in the dielectric layer 226 through an appropriate etching process and filling the trenches with a metal material. The pad layer 230 may be disposed on the dielectric layer 226 by carrying out a suitable film deposition process and a patterning process to form the pad layer 230 disposed on the plugs 228.

According to different actual testing requirements, the semiconductor manufacturing processes carried out on the main surface 210T of the test wafer base 210 may include an epitaxial process, a thin film process, an etching process, a patterning process, a grinding process, but the present invention is not limited thereto. Therefore, the ingredients or components in the thin film 220 of the test wafer 200 to be recovered in the present invention are not limited to those shown in FIG. 1 or the above-mentioned embodiments. For example, the semiconductor layers 222 within the thin film 220 may be discontinuous layers such that the dielectric layer 226 fills the gaps between the semiconductor layers 222 and contacts the main surface 210T.

Please refer to FIG. 1 for details of the first laser process, the second laser process, and the third laser process; for example, the first parameter group corresponds to the second parameter group, and/or the second parameter group corresponds to the third parameter group. According to different requirements, the test wafer 200 may be inspected by an optical inspection instrument to obtain the thickness of the thin film 220 before the first laser process so that the laser L of the first laser process can be focused on the interface between the thin film 220 and the main surface 210T, which is conducive to the rapid separation or the removal of the thin film 220.

According to different requirements, the main surface 210T may be inspected with a surface roughness meter or a scanning electron microscope (SEM) to determine if the second laser process and the third laser process are a full scan or a partial scan prior to the second laser process and the third laser process. The main purpose of the second laser process is to reduce the surface roughness increased by the first laser process on the main surface 210T so as to facilitate the smooth progress of the subsequent planarization process. In one embodiment, the second laser process and the third laser process are directly carried out following the first laser process.

When carrying out the first laser process and the second laser process, at least some of the semiconductor layer 222 adjacent to the main surface 210T of the test wafer 200, shown in FIG. 7 may be cracked, melted, or vaporized. According to different implementations, at least some of the dielectric portion, the semiconductor portion, and the conductor portion, which are adjacent to the interface of the test wafer base 210 and the thin film 220, cracked, melted, or vaporized when carrying out the first laser process and the second laser process.

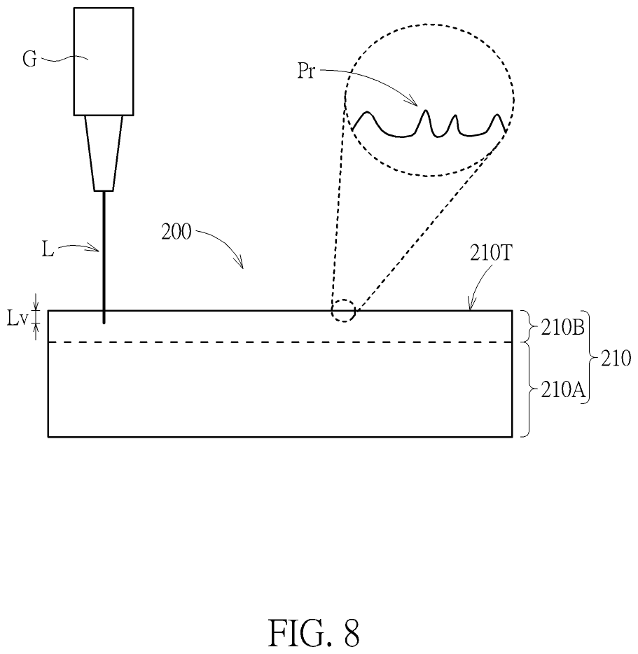

FIG. 8 illustrates a schematic diagram of performing the second laser process or the third laser process after the first laser process according to an embodiment of the present invention. The test wafer base 210 in FIG. 8 is a partial cross-sectional view and the possible thin film fragments or residues which may be left on the main surface 210T of the test wafer 200 in FIG. 4 after the first laser process are omitted. A plurality of protrusions Pr form on the main surface 210T of the test wafer 200 after removing the thin film 220 in FIG. 1 in the first laser process. In order to make the main surface 210T of the test wafer 200 meet the specification of the surface roughness of the subsequent planarization process, the protrusions Pr on the main surface 210T may be melted or vaporized by carrying out the second laser process, so that the arithmetic mean height (Ra) of the main surface 210T is less than 1 μm. In other words, the main surface 210T of the test wafer 200 has a first roughness (for example, the arithmetic mean height (Ra)) prior to the second laser process, and the main surface 210T of the test wafer 200 has a second roughness (for example, the arithmetic mean height (Ra)) following the second laser process, and the first roughness is greater than the second roughness.

In order to eliminate the damage caused by the first laser process to the test wafer base 210, such as lattice dislocation or contaminant doping, but the present invention is not limited thereto, a third laser process may be further carried out to anneal the test wafer base 210 to effectively reduce or eliminate the insertional oxygen defect of the surface layer 210B. The insertion-type oxygen defects include generated point defects due to oxygen precipitation. The damage caused by the first laser process is distributed on the surface layer 210B of the test wafer base 210, and the crystallinity of the surface layer 210B may be changed by the third laser process, thereby releasing the stress of the surface layer 210B. Specifically speaking, the entropy of the surface layer 210B may be accordingly reduced, and microscopically speaking, the amorphous region or the polycrystalline region may be repaired to yield a single crystal lattice arrangement.

The first parameter group of the first laser process, such as but not limited to the first focal offset distance, the first pulse frequency, the first power density, and the first pulse width; the second parameter group of the second laser process, such as but not limited to, the second focal offset distance, the second pulse frequency, the second power density, and the second pulse width; the third parameter group of the third laser process, such as but not limited to, the third focal offset distance, the third pulse frequency, the third power density, and the third pulse width. The focal offset distance Lv of the second laser process and the third laser process may be adjusted according to the damage caused by the first laser process and the desired surface roughness. In one embodiment, the focal offset distance Lv of the laser L of the second laser process and the third laser process ranges from 0.01 μm to 10 μm under the main surface 210T. In one embodiment, the pulse frequency of the first laser process, the second laser process, and the third laser process range from 10 kHz to 100 kHz, and the pulse width ranges from 100 nanoseconds to 500 nanoseconds. The first power density of the first laser process can range from 500 μJ/pulse to 700 μJ/pulse, the second power density of the second laser process ranges from 200 μJ/pulse to 500 μJ/pulse, and the third power density of the third laser process is less than 200 μJ/pulse. In another embodiment, the first power density of the first laser process ranges from 600 μJ/pulse to 800 μJ/pulse, the second power density of the second laser process ranges from 300 μJ/pulse to 600 μJ/pulse, and the third power density of the third laser process is less than 300 μJ/pulse. It should be noted that the power density of the present invention is the energy of each laser pulse, and the energy received by the irradiated surface of the wafer per unit of time is not only related to the power density but also related to the pulse width. Specifically speaking, the energy (μJ/ns) received by the irradiated surface of the wafer may be obtained by dividing the power density by the pulse width.

According to different requirements, the first laser process, the second laser process, and the third laser process may be pulse lasers with the same or different pulse widths. In one embodiment, the first laser process and the second laser process may be nanosecond laser, picosecond laser, or femtosecond laser, and the third laser process may be nanosecond laser. By using a pulse laser, selected local regions may be cracked, melted, or vaporized without affecting unselected regions.

According to actual requirements, the main surface 210T of the recovered test wafer 200 may be modified. For example, the first laser process, the second laser process, or the third laser process may be carried out under an oxygen atmosphere to thermally oxidize some of the single-crystal silicon surface layer 210B into silicon dioxide. Alternatively, the main surface 210T of the test wafer 200 may be coated with a hydrophilic polymer (for example, a photo-curable water-based covering material), and the hydrophilic polymer may be cured onto the main surface 210T by the laser L to obtain a hydrophilic surface when the third laser process is carried out.

According to the above embodiments, the test wafer is used as the main recycling target of the method for recycling the present invention, but the present invention is not limited thereto. According to the actual situations, the wafer recycling method of the present invention is not limited to the recovery of test wafers but is also applicable to the recovery of prime wafers which are not diced after being processed by processing machines (such as thin film deposition machines, etching machines, etc.). Such processed prime wafers may not be suitable for further processing to obtain semiconductor devices due to structural defects and/or electrical defects. That is, the above-mentioned test wafer and test wafer base may also be replaced with a prime wafer and a standard wafer base. According to an embodiment of the present invention, the wafer recycling method of the present invention is suitable for recycling a prime wafer with a defect on the production line. The prime wafer with a defect may be a prime wafer that is subjected to at least one process and include a thin-film dielectric portion thereon, a semiconductor portion thereon, a conductor portion thereon, or any combination thereof. By implementing the wafer recycling method of the present invention, a prime wafer with a defect may be reused as a test wafer.

The wafer recycling method may include a step K1, a step K2, a step K3, and a step K4. In step K1, a wafer is provided. In step K2, a first laser process is involved, wherein the main surface or the surface layer of the wafer is irradiated with a laser to induce separation at the interface between the main surface and the thin film. In step K3, a second laser process is involved, wherein the main surface or the surface layer of the wafer is irradiated with a laser, thereby changing the surface roughness of the main surface. In step K4, a third laser process is involved, wherein the main surface or the surface layer of the wafer is irradiated with a laser, thereby changing the crystallinity of the surface layer. According to different requirements, the order of steps K2 to K4 may be rearranged or carried out simultaneously. In one embodiment, after carrying out steps K1 to K4, the wafer recycling method further includes carrying out a planarization process (such as chemical mechanical polishing) on the main surface of the wafer and then carrying out a cleaning process (such as ultrasonic cleaning) on the main surface of the wafer.

According to the aforementioned examples of the present invention, it is possible to avoid using a wet etching thin film removal process or to reduce the number of chemicals used in the wet etching and thin film removal process to be conducive to environmental protection and sustainable development by using a laser process to remove a thin film disposed on a test wafer base or a prime wafer base (a wafer base for short). In addition, the laser can focus on the interface between the thin film and the wafer base because a pulse laser is used when removing the thin film; it may avoid laser damage to other unselected regions and accelerate the efficiency of the thin film removal. In addition, the laser process may also be used to adjust the surface roughness of the wafer base, thereby eliminating the requirement for the planarization process or reducing the processing time of the planarization process. In addition, the laser process may also be used to remove lattice defects in the surface layer of the wafer base, thereby eliminating the requirement for wet etching or heat treatment processes or reducing the processing time of the wet etching or heat treatment processes. The wafer recycling method of the present invention is environmentally friendly, safe, and simple for a manufacturing process. Thus, it meets the industrial demands for a wafer recycling method.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for a wafer treatment; comprising:
providing a wafer, wherein the wafer comprises a wafer base, the wafer base comprising a surface layer;
performing a first laser process, wherein the surface layer of the wafer is irradiated with a first laser to modify the surface layer, wherein the first laser is associated with a first parameter group; and
performing a second laser process, wherein the surface layer of the wafer is irradiated with a second laser to modify the surface layer, wherein the second laser is associated with a second parameter group;
wherein the modification of the surface layer comprises at least one of removing at least a portion of the surface layer, changing the crystallinity of the surface layer, and changing the surface roughness of the surface layer, and the first parameter group corresponds to the second parameter group.

2. The method for a wafer treatment of claim 1, wherein the wafer further comprises a thin film disposed on the wafer base and comprising a dielectric portion, a semiconductor portion, and a conductor portion, the wafer base comprises a main surface and a base layer, the method further comprises:
performing the first laser process, wherein the main surface of the wafer is irradiated with the first laser to induce separation at the interface between the main surface and the thin film;
performing the second laser process to irradiate the main surface of the wafer with the second laser, thereby changing the surface roughness of the main surface; and
performing a third laser process to irradiate the main surface or the surface layer of the wafer with a laser, thereby changing the crystallinity of the surface layer.

3. The method for a wafer treatment of claim 2, wherein the first laser process is performed prior to the second laser process and the third laser process.

4. The method for a wafer treatment of claim 2, wherein the first laser process is performed prior to the second laser process, and the second laser process is performed prior to the third laser process.

5. The method for a wafer treatment of claim 2, further comprising:
performing a planarization process on the main surface of the wafer; and
performing a cleaning process on the main surface of the wafer after performing the planarization process;
wherein a laser focal offset distance of the second laser process and the third laser process is within the surface layer.

6. The method for a wafer treatment of claim 5, wherein the laser focal offset distance of the second laser process and the laser focal offset distance of the third laser process each ranges from 0.01 μm to 10 μm under the main surface of the wafer.

7. The method for a wafer treatment of claim 2, wherein at least one of a part of the dielectric portion, a part of the semiconductor portion, and a part of the conductor portion adjacent to the interface is degraded, melted, or vaporized when performing the first laser process and the second laser process.

8. The method for a wafer treatment of claim 2, wherein the surface roughness of the main surface is converted from a first roughness to a second roughness, and the first roughness is greater than the second roughness when performing the second laser process.

9. The method for a wafer treatment of claim 2, wherein scanning paths of the first laser and the second laser are each linear, scanning pitches of the first laser and the second laser each ranges from 1 μm to 100 μm, and scanning widths of the first laser and the second laser each range from 2 μm to 100 μm.

10. The method for a wafer treatment of claim 2, wherein an arithmetic average height (Ra) of the main surface of the wafer is less than 1 μm after performing the second laser process.

11. The method for a wafer treatment of claim 1, wherein the wafer further comprises a front side, a back side, and an edge, and at least one of the front side, the back side, and the edge has a damaged surface layer, the method further comprises:
performing the first laser process to irradiate the damaged surface layer of the wafer with the first laser to remove the damaged surface layer, wherein the first laser is characterized by the first parameter group, which comprises a first power density, a first spot size, and a first focal offset distance during the first laser process; and
performing the second laser process after the first laser process, where the front side and the back side of the wafer are irradiated with the second laser during the second laser process to thereby reduce the surface roughness of the front side and the back side, wherein
the second laser is characterized by the second parameter group comprising a second power density, a second spot size and a second focal offset distance,
values of at least two of the second power density, second spot size, and the second focal offset distance are smaller than their corresponding values in the first parameter group.

12. The method for a wafer treatment of claim 11, wherein the damaged surface layer comprises a plurality of cutting marks and a plurality of structural defects.

13. The method for a wafer treatment of claim 11, wherein the wafer is obtained by cutting a silicon ingot, and the damaged surface layer is produced when cutting the silicon ingot.

14. The method for a wafer treatment of claim 11, after performing the second laser process further comprising:
performing a third laser process, wherein the front side, the back side, and the edge are irradiated with a laser to anneal the front side, the back side, and the edge, wherein
the laser has a third power density and a third spot size, and the third power density is smaller than the first power density and the second power density, and the third spot size is larger than the first spot size and the second spot size when performing the third laser process.

15. The method for a wafer treatment of claim 14, wherein the laser in the third laser process is a nanosecond laser.

16. The method for a wafer treatment of claim 14, wherein the diameter of the spot size of the laser in the third laser process is larger than 0.5 mm.

17. The method for a wafer treatment of claim 11, wherein a diameter of the first spot size is greater than 0.05 mm, and a diameter of the second spot size is less than 20 μm.

18. The method for a wafer treatment of claim 11, wherein scanning paths of the first laser and of the second laser are each linear, scanning pitches of the first laser and of the second laser each ranges from 1 μm to 100 μm, and scanning widths of the first laser and the second laser each ranges from 2 μm to 10 μm.

19. The method for a wafer treatment of claim 11, wherein the second focal offset distance is within 10 μm below the front side and the back side of the wafer or is located on a surface of the front side and the back side.

20. The method for a wafer treatment of claim 11, wherein a planarization process is performed on the front side and the back side to further reduce the surface roughness of the front side and the back side after performing the second laser process.
